(19) United States
(12) Patent Application Publication
(10) Pub. No.: US 2025/0077804 A1
(43) Pub. Date: Mar. 6, 2025

(54) POWER-EFFICIENT MIXED-SIGNAL CIRCUIT INCLUDING ANALOG MULTIPLY AND ACCUMULATE ENGINES

(71) Applicant: INTERNATIONAL BUSINESS MACHINES CORPORATION, ARMONK, NY (US)

(72) Inventors: Ankur Agrawal, Chappaqua, NY (US); Andrea Fasoli, San Jose, CA (US); Monodeep Kar, New York, NY (US); Kyu-hyoun Kim, Chappaqua, NY (US); Sergey Rylov, White Plains, NY (US); Chia-Yu Chen, Westchester, NY (US); Xiao Sun, Pleasantville, NY (US)

(21) Appl. No.: 18/458,141

(22) Filed: Aug. 29, 2023

(51) Int. Cl. G06G 7/32

(52) U.S. Cl. CPC G06G 7/32; H03M 1/12

(57) ABSTRACT

A first circuit is configured to split a first integer value into a first coarse value and a first fine value, and split a second integer value into a second coarse value and a second fine value. A second circuit performs an analog multiply and accumulate (MAC) operation on the first and second coarse values to produce a first analog output, perform an analog MAC operation on the first coarse value and the second fine value to produce a second analog output, perform an analog MAC operation on the first fine value and the second coarse value to produce a third analog output, and perform an analog MAC operation on the first and second fine values together to produce a fourth analog output. A third circuit is configured to perform analog-to-digital (A/D) conversion on and combine the analog output signals to produce a reconstructed digital output signal.

### BACKGROUND

### Technical Field

The present disclosure generally relates to circuits for performing matrix multiplication, and more particularly, to mixed-signal circuits that include analog multiply and accumulate units for performing matrix multiplication.

### Description of the Related Art

Matrix multiplication is performed in many machine learning algorithms, including neural networks. Matrix multiplication is also performed in graphics processing, scientific computations, Internet searching, etc.

Matrix multiplication may be performed in the digital domain by parallel processing units, or it may be performed in the analog domain by multiply and accumulate (MAC) units. MAC units based on switched capacitors offer greater power efficiency than digital processing units. Greater power efficiency is desirable for certain devices, such as edge computing devices at the edges of distributed networks.

### SUMMARY

According to an embodiment of the present disclosure, a system includes first, second and third circuits. The first circuit is configured to split a first integer value into a first coarse value and a first fine value, and split a second integer value into a second coarse value and a second fine value. The second circuit is configured to perform an analog multiply and accumulate (MAC) operation on the first and second coarse values to produce a first analog output signal, perform an analog MAC operation on the first coarse value and the second fine value to produce a second analog output signal, perform an analog MAC operation on the first fine value and the second coarse value to produce a third analog output signal; and perform an analog MAC operation on the first and second fine values to produce a fourth analog output signal. The third circuit is configured to perform analog-to-digital (A/D) conversion on and combine the analog output signals to produce a reconstructed digital output signal.

In some embodiments, which can be combined with the preceding embodiment, the second circuit is further configured to perform most significant bit (MSB) skipping during the A/D conversion. Between two and four bits may be skipped.

In some embodiments, which can be combined with the preceding embodiments, the first circuit is configured to receive a first vector having M integer values and a second vector having M integer values, where integer M>1 and where the first vector includes the first integer value and additional integer values, and the second vector includes the second value and additional integer values; split the first vector into a first coarse value vector and a first fine value vector; and split the second vector into a second coarse value vector and a second fine value vector. The second circuit is configured to generate the first analog signal as a dot product of the first and second coarse value vectors, the second analog signal as a dot product of the first coarse and second fine value vectors, the third analog signal as a dot product of the first fine and second coarse value vectors, and the fourth analog signal as a dot produce of the first and second fine value vectors. The third circuit is configured to perform the A/D conversion and combine the analog output signals after M accumulations have been completed.

In some embodiments, which can be combined with one or more preceding embodiments, the A/D conversions are then performed at less than full precision, where full precision is defined as 2X+log 2(M), where X is bit width of the first and second integer values.

In some embodiments, which can be combined with one or more preceding embodiments, a first MAC engine is configured to produce the first analog output signal, and a first A/D converter is operative on the first analog output; a second MAC engine is configured to produce the second analog output signal, and a second A/D converter is operative on the second analog output; a third MAC engine is configured to produce the third analog output signal and a third A/D converter is operative on the third analog output; and a fourth MAC engine is configured to produce the fourth analog output signal, and a fourth A/D converter is operative on the fourth analog output. Digital signals outputted by the A/D converters are shifted and summed to produce the reconstructed digital output signal.

In some embodiments, which can be combined with one or more preceding embodiments, the second circuit includes a plurality of switched capacitor-based MAC engines for performing the MAC operations.

In some embodiments, which can be combined with one or more preceding embodiments, least significant bit (LSB) truncation may be performed during A/D conversion.

In some embodiments, which can be combined with one or more preceding embodiments, full-scale range of the A/D conversion is lower than dynamic range of the analog output signals to perform MSB skipping during the A/D conversion.

In some embodiments, which can be combined with one or more preceding embodiments, the third circuit further includes first, second, third and fourth amplifiers for increasing signal amplitude beyond full-scale input ranges of the first, second, third and fourth A/D converters, respectively.

In some embodiments, which can be combined with one or more preceding embodiments, the first and second integer values are represented by 8 bits, the first and second coarse values are represented by 4 bits, and the first and second fine values are represented by 4 bits. Each fine value has a rounded LSB. The digital output signal is reconstructed as

$${Y}_{R} = {2}^{8} Z 0 + {2}^{5} Z 1 + {2}^{5} Z 2 + {2}^{2} Z 3$$

where Y_{R} is the reconstructed digital output signal, and Z0, Z1, Z2 and Z3 are the A/D conversions of the first, second, third and fourth analog output signals, respectively.

In some embodiments, which can be combined with one or more preceding embodiments, the first and second integer values are represented by 8 bits, the first and second coarse values are represented by 4 bits, and the first and second fine values are represented by 5 bits. The digital output signal is reconstructed as

$${Y}_{R} = {2}^{8} Z 0 + {2}^{4} Z 1 + {2}^{4} Z 2 + Z 3$$

where Y_{R} is the reconstructed digital output signal, and Z0, Z1, Z2 and Z3 are the A/D conversions of the first, second, third and fourth analog output signals, respectively.

According to an embodiment of the present disclosure, there is a computer-implemented method of multiplying first and second input vectors. Each of the input vectors has M integer values. The method includes splitting values of the first input vector into first coarse value vectors and first fine value vectors; splitting values of the second input vector into second coarse value vectors and second fine value vectors; and using a plurality of analog multiply and accumulate (MAC) units to generate a first analog signal representing a dot product of the first and second coarse value vectors, a second analog signal representing a dot product of the first coarse and second fine value vectors, a third analog signal representing a dot product of the first fine and second coarse value vectors, and a fourth analog signal representing a dot produce of the first and second fine value vectors. The method further includes performing A/D conversion on and combining the first, second, third and fourth analog signals to produce a digital output signal representing a dot product of the first and second input vectors.

According to an embodiment of the present disclosure, a computing device for running a neural network includes a plurality of switched capacitor units for performing matrix multiplication on an input vector and a weight vector. Each switched capacitor unit is configured to split values of an input vector into first coarse value vectors and first fine value vectors; split values of a weight vector into second coarse value vectors and second fine value vectors; perform analog multiply and accumulate (MAC) operations to take a first dot product of the first and second coarse value vectors, a second dot product of the first coarse and second fine value vectors, a third dot product of the first fine and second coarse value vectors, and a fourth dot produce of the first and second fine value vectors; and perform A/D conversion on and combine the first, second, third and fourth dot products to produce a reconstructed digital signal. The computing device further includes a digital processor programmed to apply activation functions to the outputs of the switched capacitor units.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 is a mixed signal circuit, consistent with an illustrative embodiment.

FIG. 2 illustrates first and second INT8 values represented as coarse INT4 values and fine INT4 values, consistent with an illustrative embodiment.

FIG. 3 is a method of using the mixed signal circuit of FIG. 1, consistent with an illustrative embodiment.

FIG. 4 is a method of generating a digital output signal at full precision, consistent with an illustrative embodiment.

FIG. 5 is a method of generating a digital output signal at less than full precision, consistent with an illustrative embodiment.

FIG. 6 is a mixed signal circuit including amplifiers for MSB skipping, consistent with an illustrative embodiment.

FIG. 7 illustrates first and second INT8 values represented as coarse INT4 values and fine INT5 values, consistent with an illustrative embodiment.

FIG. 8 is a MAC processor based on switched capacitors, consistent with an illustrative embodiment.

FIG. 9 is a computing system, consistent with an illustrative embodiment.

FIG. 10 is an illustration of a signal that is amplified for MSB skipping, consistent with an illustrative embodiment.

### DETAILED DESCRIPTION

### Overview

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

The present disclosure generally relates to mixed signal circuits including analog multiply and accumulate engines for performing vector multiplication. By virtue of the concepts discussed herein, power efficiency of the mixed signal circuits is increased.

According to an embodiment of the present disclosure, a system includes first, second and third circuits. The first circuit is configured to split a first integer value into a first coarse value and a first fine value, and split a second integer value into a second coarse value and a second fine value. The second circuit is configured to perform an analog multiply and accumulate (MAC) operation on the first and second coarse values to produce a first analog output signal, perform an analog MAC operation on the first coarse value and the second fine value to produce a second analog output signal, perform an analog MAC operation on the first fine value and the second coarse value to produce a third analog output signal; and perform an analog MAC operation on the first and second fine values to produce a fourth analog output signal. The third circuit is configured to perform analog-to-digital (A/D) conversion on and combine the analog output signals to produce a reconstructed digital output signal.

Analog MAC engines in general are more power-efficient at performing vector multiplication than digital processors. However, some (if not all) of that efficiency gain is lost during A/D conversion. The system enables vector multiplications to preserve some of that efficiency gain during A/D conversion, while retaining accuracy of the digital output signal.

In some embodiments, the second circuit may be configured to perform most significant bit (MSB) skipping during the A/D conversion. The MSB skipping makes the A/D conversion more efficient. The digital output signal is not fully accurate, but it may be accurate enough for its application domain.

In some embodiments, the third circuit may be configured to perform LSB truncation during the A/D conversion. Power efficiency may be further improved by the LSB truncation.

In some embodiments, power efficiency may be further improved with the combination of MSB skipping and LSB truncation.

In some embodiments, the first circuit is configured to receive a first vector having M integer values and a second vector having M integer values, where integer M>1 and where the first vector includes the first integer value and additional integer values and the second vector includes the second value and additional integer values; split the first vector into a first coarse value vector and a first fine value vector; and split the second vector into a second coarse value vector and a second fine value vector. The second circuit is configured to generate the first analog signal as a dot product of the first and second coarse value vectors, the second analog signal as a dot product of the first coarse and second fine value vectors, the third analog signal as a dot product of the first fine and second coarse value vectors, and the fourth analog signal as a dot produce of the first and second fine value vectors. The third circuit is configured to perform the A/D conversion and combine the analog output signals after M accumulations have been completed.

In some embodiments, after the M accumulations have been completed, the A/D conversion is performed at less than full precision, where full precision may be defined as 2N+log 2(M), where N is bit width of the first and second integer values. Power efficiency may be further improved by performing the A/D conversion at less than full precision.

In some embodiments, a first MAC engine is configured to produce the first analog output signal, and a first A/D converter is operative on the first analog output; a second MAC engine is configured to produce the second analog output signal, and a second A/D converter is operative on the second analog output; a third MAC engine is configured to produce the third analog output signal and a third A/D converter is operative on the third analog output; and a fourth MAC engine is configured to produce the fourth analog output signal, and a fourth A/D converter is operative on the fourth analog output. Digital signals outputted by the A/D converters are shifted and summed to produce the reconstructed digital output signal. Power efficiency is further improved by performing all A/D conversions at less than full precision.

In some embodiments, which can be combined with the preceding embodiments, the MAC engines are based on switched capacitors.

In some embodiments, which can be combined with the preceding embodiments, MSB skipping in the A/D converters causes between two and four of the most significant bits to be skipped.

In some embodiments, which can be combined with the preceding embodiments, full-scale range of the A/D conversion is lower than dynamic range of the analog output signals to perform MSB skipping during the A/D conversion and thereby improve power efficiency.

In some embodiments, which can be combined with one or more of the preceding embodiments, the third circuit further includes first, second, third and fourth amplifiers for increasing signal amplitude beyond full-scale input ranges of the first, second, third and fourth A/D converters, respectively, to perform MSB skipping and thereby improve power efficiency.

In some embodiments, the integer values of the first and second vectors are N bits wide, the integer values of the coarse value vectors are K bits wide, and the integer values of the fine value vectors are Y bits wide, where Y<N and K<N.

In some embodiments, which can be combined with one or more of the preceding embodiments, the first and second integer values are represented by 8 bits, the first and second coarse values are represented by 4 bits, and the first and second fine values are represented by 4 bits. Each fine value has a rounded LSB. The digital output signal is reconstructed as:

$${Y}_{R} = {2}^{8} Z 0 + {2}^{5} Z 1 + {2}^{5} Z 2 + {2}^{2} Z 3$$

where Y_{R} is the reconstructed digital output signal, and Z0, Z1, Z2 and Z3 are the A/D conversions of the first, second, third and fourth analog output signals, respectively.

In some embodiments, which can be combined with one or more of the preceding embodiments, the first and second integer values are represented by 8 bits, the first and second coarse values are represented by 4 bits, and the first and second fine values are represented by 5 bits. The digital output signal is reconstructed as:

$${Y}_{R} = {2}^{8} Z 0 + {2}^{4} Z 1 + {2}^{4} Z 2 + Z 3$$

where Y_{R} is the reconstructed digital output signal, and Z0, Z1, Z2 and Z3 are the A/D conversions of the first, second, third and fourth analog output signals, respectively.

According to an embodiment of the present disclosure, there is a computer-implemented method of multiplying first and second input vectors. Each of the input vectors has M integer values. The method includes splitting values of the first input vector into first coarse value vectors and first fine value vectors; splitting values of the second input vector into second coarse value vectors and second fine value vectors; and using a plurality of analog MAC units to generate a first analog signal representing a dot product of the first and second coarse value vectors, a second analog signal representing a dot product of the first coarse and second fine value vectors, a third analog signal representing a dot product of the first fine and second coarse value vectors, and a fourth analog signal representing a dot produce of the first and second fine value vectors. The method further includes performing A/D conversion on and combining the first, second, third and fourth analog signals to produce a digital output signal representing a dot product of the first and second input vectors.

In some embodiments of the computer-implemented method, most significant bit skipping is performed during A/D conversion.

The improvement in power efficiency is especially valuable for edge computing devices at the edges of a distributed system. Applications performed by such devices include, but are not limited to, neural networks and other machine learning models, graphics, scientific computation, and Internet searching.

According to an embodiment of the present disclosure, a computing device runs a neural network. The computing device includes a plurality of switched capacitor units for performing matrix multiplication on an input vector and a weight vector. Each switched capacitor unit is configured to split values of an input vector into first coarse value vectors and first fine value vectors; split values of a weight vector into second coarse value vectors and second fine value vectors; perform analog multiply and accumulate (MAC) operations to take a first dot product of the first and second coarse value vectors, a second dot product of the first coarse and second fine value vectors, a third dot product of the first fine and second coarse value vectors, and a fourth dot produce of the first and second fine value vectors; and perform analog-to-digital (A/D) conversions on and combine the first, second, third and fourth dot products to produce a reconstructed digital signal. The computing device further includes a digital processor programmed to apply activation functions to the outputs of the switched capacitor units.

In some embodiments of the computing device, each switched capacitor unit includes first, second, third and fourth switched capacitor-based MAC engines configured to produce the first, second, third and fourth dot products, respectively. Each switched capacitor unit further includes first, second, third and fourth A/D converters operative on analog signals representing the first, second, third and fourth dot products, respectively; and a shift a sum circuit for combining outputs of the first, second, third and fourth A/D converters to produce the reconstructed digital signal.

In some embodiments of the computing device, full-scale ranges of the A/D converters are lower than dynamic ranges of the analog signals representing the dot products to perform MSB skipping during the A/D conversion.

In some embodiments of the computing device, each switched capacitor unit further includes first, second, third and fourth amplifiers for increasing signal amplitude beyond full-scale input ranges of the first, second, third and fourth analog-to-digital converters, respectively.

### Example Construction

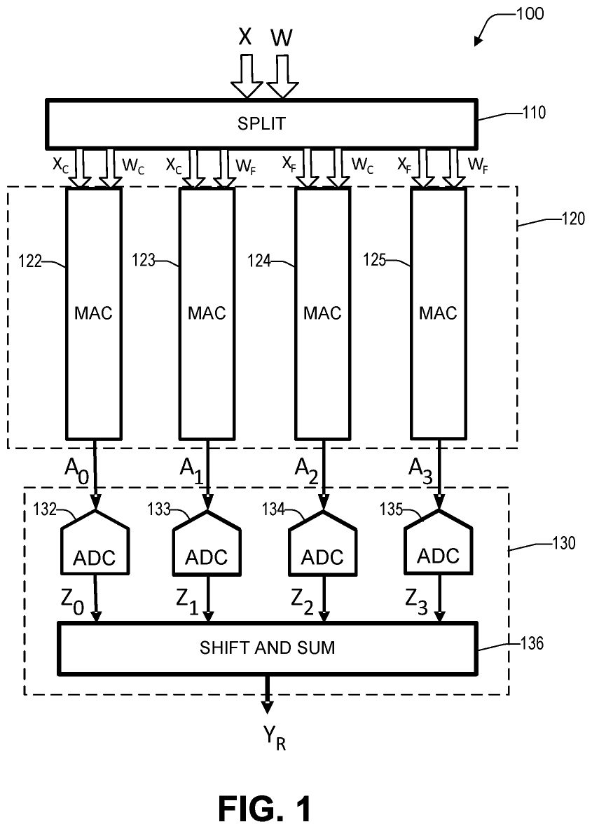

Reference is made to FIG. 1, which illustrates a mixed signal circuit 100 for performing a vector multiplication on first and second vectors X and W. Each vector X and W is an M×N vector, where integer M represents the number of words, and N represents the number of bits per word. Thus, X={x₁, . . . x_{N}} and W={w₁, . . . w_{N}}. Initially, the circuit 100 will be described for a 1×N vector, where the vector X contains a first N-bit integer value (x1), and the vector W contains a second N-bit integer value (w1).

The mixed signal circuit 100 includes first, second and third circuits 110, 120 and 130. The first circuit 110 is configured to split the first integer value x1 into a first coarse value x_{c} and a first fine value x_{F}, and split a second integer value w1 into a second coarse value w_{c} and a second fine value w_{F}. The first circuit 110 may include basic logic gates (e.g., NAND gates) for performing the splitting.

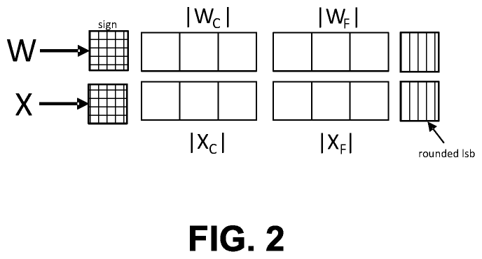

Additional reference is made to FIG. 2, which shows an example of splitting INT8 values into coarse INT4 value and fine INT4 values. INT8 is an 8-bit signed integer having a sign bit and seven magnitude bits. The first circuit 110 splits the first integer value x1 into a 4-bit first coarse value x_{c} and a 4-bit first fine value x_{F}. The first circuit 110 also splits the second integer w1 into a 4-bit second coarse value w_{c} and a 4-bit second fine value w_{F}. Each coarse value has a sign bit and three bits magnitude. Each fine value x_{F} and w_{F} has a sign bit and three bits magnitude. The least significant bit (LSB) is rounded. Different rounding strategies include, but are not limited to, nearest neighbor, truncation, and stochastic rounding.

The coarse values x_{c} and w_{c} and the fine values x_{F} and w_{F} may be represented as follows:

$$X c = sign ( X ) * Trunc ( \frac{\vert X \vert}{{2}^{4}} )$$

$${X}_{F} = sign ( X ) * Trunc ( Remainder \frac{( \vert X \vert , {2}^{4} )}{2} )$$

$$Wc = sign ( W ) * Trunc ( \frac{\vert W \vert}{{2}^{4}} )$$

$${W}_{F} = sign ( W ) * Trunc ( Remainder \frac{( \vert W \vert , {2}^{4} )}{2} )$$

Thus, the first and second integer values x1 and w1 may be approximated as:

$$x 1 ≅ {2}^{4} {X}_{C} + 2 {X}_{F}$$

$$w 1 ≅ {2}^{4} {W}_{C} + 2 {W}_{F}$$

These are approximations of integer values x1 and w1 because the rounding of the LSB may introduce some error.

Returning to FIG. 1, the second circuit 120 includes a first analog multiply and accumulate (MAC) engine 122 for performing a MAC operation on the first and second coarse values x_{c} and w_{c} to produce a first analog output signal A0, a second MAC engine 123 for performing an analog MAC operation on the first coarse value x_{c} and the second fine value w_{F} to produce a second analog output signal A1, a third MAC engine 124 for performing an analog MAC operation on the first fine value x_{F} and the second coarse value w_{c} to produce a third analog output signal A2; and a fourth MAC engine 125 for performing an analog MAC operation on the first and second fine values x_{F} and w_{F} to produce a fourth analog output A3. Thus,

$$A 0 = {x}_{C} {w}_{C} , A 1 = {x}_{C} {w}_{F} , A 2 = {x}_{F} {w}_{C} , and A 3 = {x}_{F} {w}_{F} .$$

The third circuit 130 is configured to perform A/D conversion on and combine the analog output signals A0, A1, A2 and A3 to produce a reconstructed digital output signal. In the embodiment illustrated in FIG. 1, first, second, third and fourth A/D converters 132, 133, 134 and 135 are configured to perform A/D conversion on the analog output signals A0, A1, A2 and A3. The A/D converters 132, 133, 134 and 135 produce digital signals Z0, Z1, Z2 and Z3, respectively. The A/D converters 132, 133, 134 and 135 may perform the A/D conversion at full precision. Full precision may be defined as 2N+log 2(M), where N is bit width of the first and second integer values. However, as described herein, the splitting into four MAC channels enables the A/D conversion to be performed advantageously at less than full precision.

The third circuit 130 further includes a shift-and-sum circuit 136 for combining the converted output signals Z0, Z1, Z2 and Z3 into a reconstructed digital output signal Y_{R}. The digital signal Z0 is shifted by eight bits, the digital signal Z1 is shifted by five bits, the digital signal Z2 is shifted by five bits, and the digital signal Z3 is shifted by two bits. These shifted digital signals 2⁸Z0, 2⁵Z1, 2⁵Z2 and 2²Z3 are summed to produce a reconstructed digital output Y_{R}. Thus,

$${Y}_{R} = {2}^{8} Z 0 + {2}^{5} Z 1 + {2}^{5} Z 2 + {2}^{2} Z 3 .$$

The shift and sum circuit 136 may be implemented with shift registers and adders.

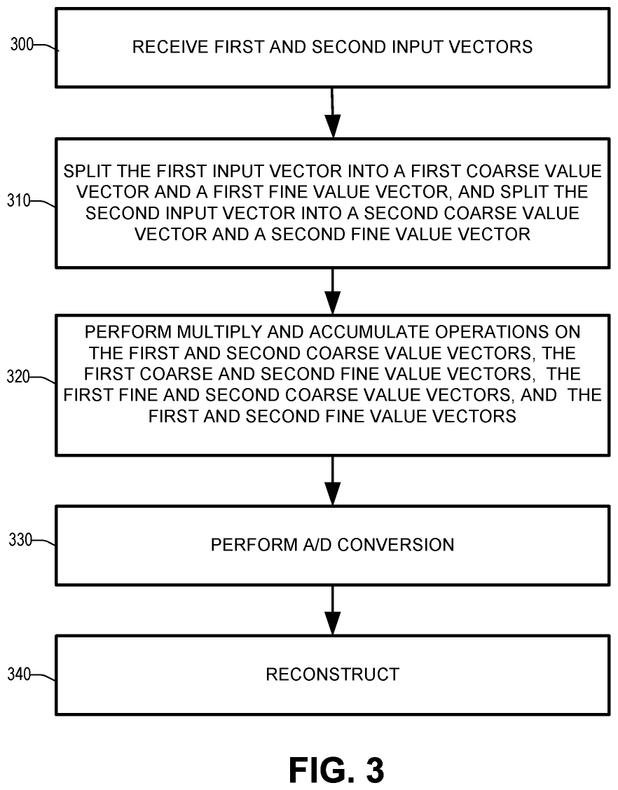

Reference is now made to FIG. 3, which illustrates a method of using the mixed signal circuit 100 of FIG. 1. In the method of FIG. 3, M>1.

At block 300, first and second input vectors X and W are received. Each input vector X, W is an M×N vector. For example, each input vector X,W has M=512 integer values and N=8 bits per value.

At block 310, the first circuit 110 is used to split the first input vector X into a first coarse value vector X_{C} and a first fine value vector X_{F}. The first circuit 110 is also used to split the second input vector W into a second coarse value vector We and a second fine value vector W_{F}.

The first coarse value vector X_{C} refers to a vector of the coarse values in X. Thus,

$${X}_{C} = \{ {x}_{c 1} , … , {x}_{c M} \} .$$

Similarly, the first fine value vector X_{F} refers to a vector of the fine values in X, the second coarse value vector W_{c} refers to a vector of the coarse values in W, and the second fine value vector X_{F} refers to a vector of the fine values in W. Thus

$${X}_{F} = \{ {x}_{f 1} , … , {X}_{fM} \}$$

$${W}_{C} = \{ {w}_{c 1} , … , {w}_{cM} \}$$

$${W}_{F} = \{ {w}_{f 1} , … , {w}_{fM} \} .$$

At block 320, the first MAC engine 122 is used to perform a multiply and accumulate operation on the first and second coarse value vectors X_{C} and W_{C}. The output analog signal A0 of the first MAC engine 122 represents a dot product of these two vectors X_{C} and W_{C}.

The second MAC engine 123 is used to perform a multiply and accumulate operation on the first coarse and second fine value vectors X_{C} and W_{F}. The output analog signal A1 of the second MAC engine 122 represents a dot product of the of these two vectors X_{C} and W_{F}.

The third MAC engine 124 is used to perform a multiply and accumulate operation on the first fine and second coarse value vectors X_{F} and W_{C}. The output analog signal A2 of the third MAC engine 124 represents a dot product of the of these two vectors X_{C} and W_{F}.

The fourth MAC engine 125 is used to perform a multiply and accumulate operation on the first and second fine value vectors X_{F} and W_{F}. The output analog signal A3 of the fourth MAC engine 125 represents a dot product of these two vectors X_{F} and W_{F}.

At the end of block 320, a total of M accumulations have been performed by each MAC engine 122, 123, 124 and 125.

At block 330, the A/D converters 132, 133, 134 and 135 perform A/D conversion on the analog signals A0, A1, A2 and A3 outputted by the first, second, third, and fourth MAC engines 122, 123, 124 and 125 to produce first, second, third and fourth digital values Z0, Z1, Z2 and Z3.

At block 340, the first, second, third and fourth digital values Z0, Z1, Z2 and Z3 are shifted and linearly combined to produce a reconstructed digital output signal Y_{R}. The reconstructed digital output signal Y_{R} represents a dot product of the first and second input vectors X and W.

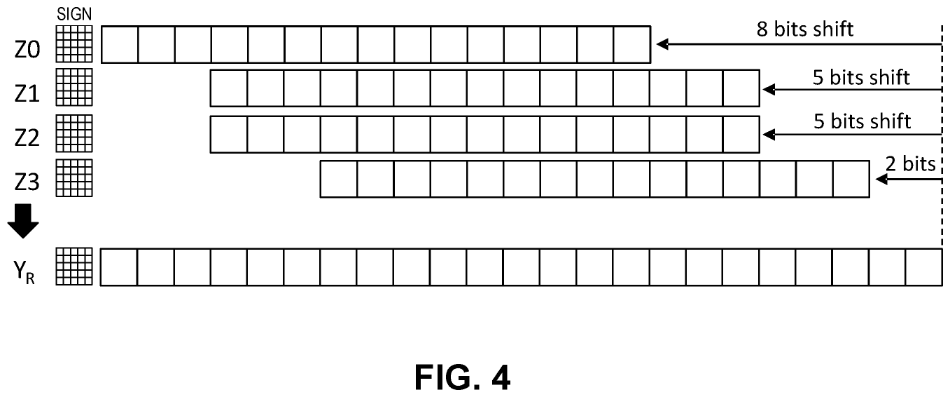

Reference is made to FIG. 4, which illustrates a reconstructed digital output signal Y_{R} where the A/D converters 132, 133, 134 and 135 perform the A/D conversion at full precision. Each of the converted output signals Z0, Z1, Z2 and Z3 at full precision A/D conversion has 2N+log(M) magnitude bits and one sign bit. For example, if M=2⁹ accumulations, and each of the digital values Z0, Z1, Z2 and Z3 has a sign bit and 3 magnitude bits, then each of the digital values Z0, Z1, Z2 and Z3 at full precision has 2(3)+9=15 magnitude bits and one sign bit. The reconstructed signal Y_{R} has 23 magnitude bits and one sign bit. This is the same number of bits as the product of two INT8 vectors without the splitting.

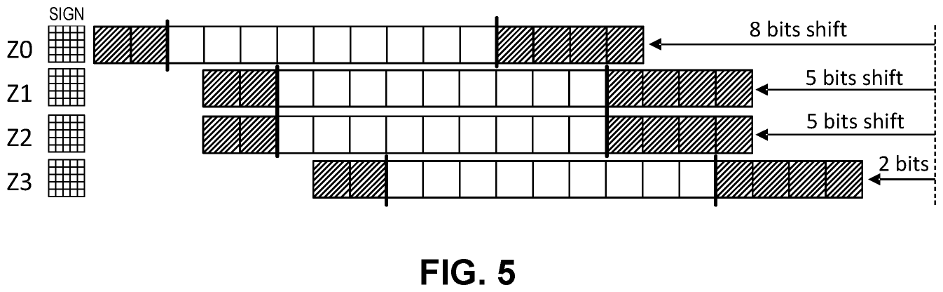

Reference is made to FIG. 5, which illustrates a reconstructed signal Y_{R} where the A/D converters perform the A/D conversion at less than full precision. Less than full precision may be achieved by performing least significant bit (LSB) truncation, or most significant bit (MSB) skipping, or a combination of LSB truncation and MSB skipping.

The A/D converters 132, 133, 134 and 135 may be configured to perform LSB truncation. In some embodiments, the A/D converters 132, 133, 134 and 135 may omit circuitry for converting the least significant bits. In other embodiments the A/D converters 132, 133, 134 and 135 may perform A/D conversion one bit at time until enough bits have been converted. In the example of FIG. 5, the four least significant magnitude bits are truncated.

To perform MSB skipping, the third circuit 130 may be configured such that full-scale range of the A/D conversion is lower than dynamic range of the analog output signals A0, A1, A2 and A3. In the example of FIG. 5, the two most significant magnitude bits are skipped.

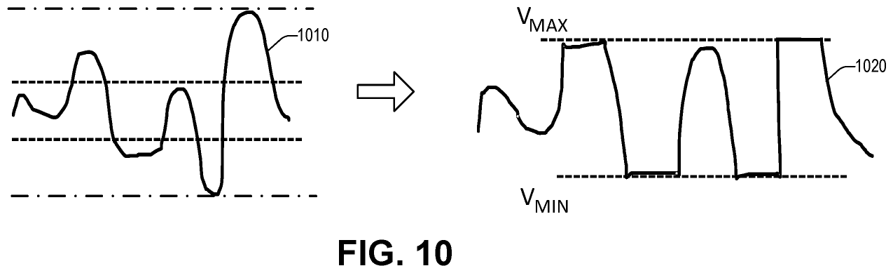

Reference is now made to FIG. 10, which illustrates an example of an analog signal 1010 at full range prior to MSB skipping. The dot-dash lines indicate the full dynamic range of the analog signal 1010. The dash lines indicate full scale input range of A/D conversion.

Because the dynamic range of the analog signal 1010 is beyond the full scale input range of A/D conversion, those portions of the analog signal 1010 are saturated to V_{MAX} and V_{MIN}. A/D conversion is performed on a clipped analog signal 1020.

The number of bits to skip may be application-specific. Generally, skipping two to four bits can result in a significant improvement in power efficiency.

Thus, the MSB skipping and the LSB truncation allow each A/D converter 132, 133, 134 and 135 to perform A/D converter on 9 magnitude bits instead of 15 magnitude bits. Resulting are substantially smaller A/D converters 132, 133, 134 and 135 that consume less power.

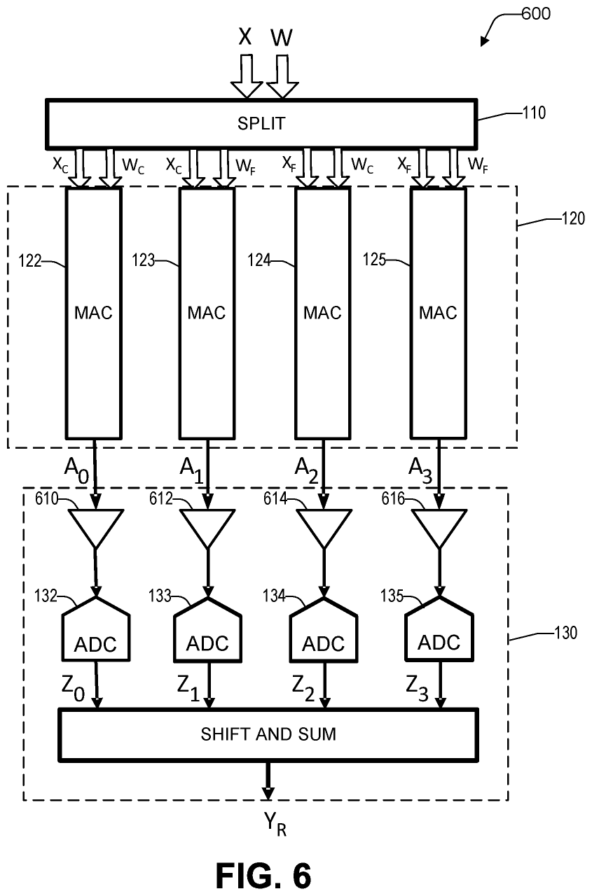

Reference is now made to FIG. 6, which shows an alternative approach towards MSB skipping. The circuit 600 of FIG. 6 has the same elements as the circuit of FIG. 1, except that the third circuit 130 further includes first, second, third and fourth amplifiers 610, 612, 614 and 616 operative on the first, second, third and fourth analog output signals A0, A1, A2, and A3, respectively. The amplifiers 610, 612, 614 and 616 are configured to increase the signal amplitude of the analog output signals A0, A1, A2, and A3 beyond full-scale input range of the A/D converters 132, 133, 134 and 135. In this manner, MSB skipping is performed.

A mixed signal circuit herein is not limited to splitting N-bit integer values into coarse values having N/2 bits and fine values having N/2 bits. For example, the coarse values may be INT4 values, and the fine values may be INT5 values.

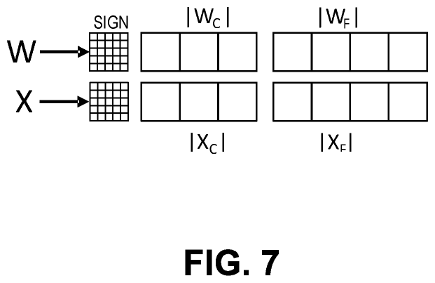

Reference is now made to FIG. 7, which shows an example of splitting vectors X and W of INT8 values into vectors X_{C} and W_{C} of coarse INT4 values and vectors X_{F} and W_{F} of fine INT5 values. Each i^{th} coarse value x_{Ci} and w_{Ci} has a sign bit and three magnitude bits. Each i^{th} fine value x_{Fi} and w_{Fi} has a sign bit and four magnitude bits. The LSB is not rounded. Values in the coarse value vectors X_{C} and We and the fine value vectors X_{F} and W_{F} may be represented as follows:

$$Xc = sign ( X ) * Trunc ( \frac{\vert X \vert}{{2}^{4}} )$$

$${X}_{F} = sign ( X ) * Trunc ( Remainder \frac{( \vert X \vert , {2}^{4} )}{2} )$$

$$Wc = sign ( W ) * Trunc ( \frac{\vert W \vert}{{2}^{4}} )$$

$${W}_{F} = sign ( W ) * Remainder \frac{( \vert W \vert , {2}^{4} )}{2}$$

After each MAC engine 122, 123, 124 and 125 has completed M accumulations, the outputs of the MAC engines 122, 123, 124 and 125 are A/D converted, and the resulting digital values Z0, Z1, Z2 and Z3 are shifted and combined as follows to produce the reconstructed output signal Y_{R}:

$${Y}_{R} = {2}^{8} Z 0 + {2}^{4} Z 1 + {2}^{4} Z 2 + Z 3 .$$

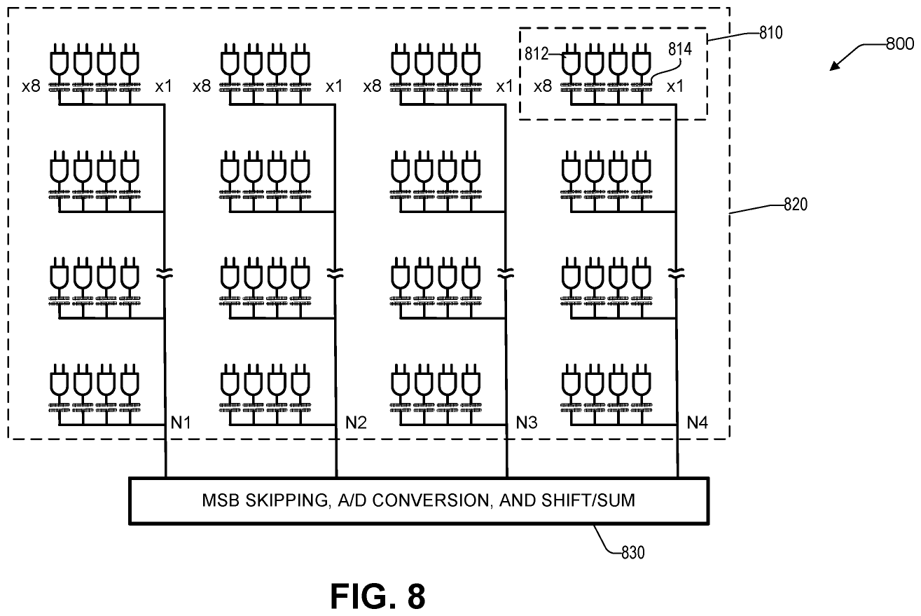

Reference is now made to FIG. 8, which illustrates an example of a MAC processor 800 that is based on switched capacitors. The MAC processor 800 includes a second circuit 820 for performing MAC operations. The second circuit 820 includes four columns of cells 810. Each cell 810 includes four AND gates 812 and four capacitor units 814 for performing a 4b×1b multiplication. The M rows correspond to M multiplies and accumulations. Each column performs M 4b×1b multiplication in parallel.

Each capacitor unit 814 may include differential first and second capacitors. The differential capacitors can store a +1 unit of charge or −1 unit of charge.

Each column is configured for INT5 operations. The four AND gates 812 and the four capacitor units 814 correspond to the four magnitude bits. The notations “x8” and “x1” denote that a capacitor in the leftmost unit 814 in a cell 810 is eight times the size of a capacitor in the rightmost unit 814. The capacitors in a cell are x1, x2, x4 and x8 (right to left). This done to implement a 4b×1b multiplication in the charge domain.

Consider an example in which vectors X and W are unsigned (for simplicity), and one input to each of the four AND gates 812 in the cell 810 of the rightmost column is X(0) bit and the other input is W(3), W(2), W(1) and W(0) respectively. Thus, the cell 810 contributes charge equal to the 4b×1b product to the node N4. Going down the rightmost column, a total of M such terms are summed to perform an M-way MAC, and node N4 has charge corresponding to the 4b×1b×M way MAC. The corresponding cell to the left of 810 performs the same operation, except that inputs to the AND gates are now X(1) [shared] and W(3), W(2), W(1) and W(0). Node N3 thus develops charge corresponding to another 4b×1b×M way MAC.

Thus, accumulated charge at node N1 represents the dot product of the coarse value vectors. Accumulated charge at node N2 represents the dot product of the first coarse and second fine value vectors. Accumulated charge at node N3 represents the dot product of the first fine and second coarse value vectors. Accumulated charge at node N4 represents the dot product of the fine value vectors.

The MAC processor 800 includes a third circuit 830 for converting and combining analog signals provided by the second circuit 820. The third circuit 830 includes one or more analog-to-digital converters operative on the analog signals representing the first, second, third and fourth dot products, respectively, and the third circuit 830 may be configured to perform MSB skipping, or LSB truncation, or both.

The example above assumes X(3:0) and W(3:0) are unsigned. For signed values, the circuits 820 and 830 would be modified to perform mathematically correct operations and the ability to sum +ve and −ve charge packets on the nodes N1, N2, N3 and N4.

Each A/D converter may be a successive approximation register (SAR) A/D converter. A SAR A/D converter converts the amplified analog signal into a discrete digital representation using a binary search through all possible quantization levels before finally converging upon a digital output for each conversion.

A mixed signal circuit herein can be configured to enable a choice between different levels of approximation. For example, the mixed signal circuit 100 of FIG. 1 can be modified to select additional modes of operation, such as a single INT8 MAC operation and a single INT4 operation (1×INT4). For these additional modes, circuitry may be added to configure how the first circuit 110 splits the input vectors, and the shift-and-sum circuit 136 may be modified so it can be bypassed.

The choice between different levels of approximation, in turn, enables the ability to select the most favorable set of output metrics (accuracy vs. energy efficiency vs. throughput vs. model size) to better fit the requirements of an application (e.g., a machine learning model). For instance, operating in 4×INT4 mode offers higher throughput (4× higher) but at worse overall workload accuracy. Operating in 4×INT4 mode also allows weights to be stored for a twice as large neural network trained model compared to INT8 mode. Thus, overall, lower precision computation not only improves energy efficiency directly (by simplifying computations), but also streamlines data movement costs.

Thus, in one aspect, disclosed are power-efficient mixed signal circuits that compute the dot product of two vectors. For systems that perform matrix multiplication-style computation on a large scale, where arrays of such circuits are used, the improvement in power efficiency is significant. The improvement in power efficiency is especially valuable for edge computing devices that run applications that include, but are not limited to, neural networks and other machine learning models, graphics, scientific computation, and Internet searching.

### Example Particularly Configured for Neural Networks

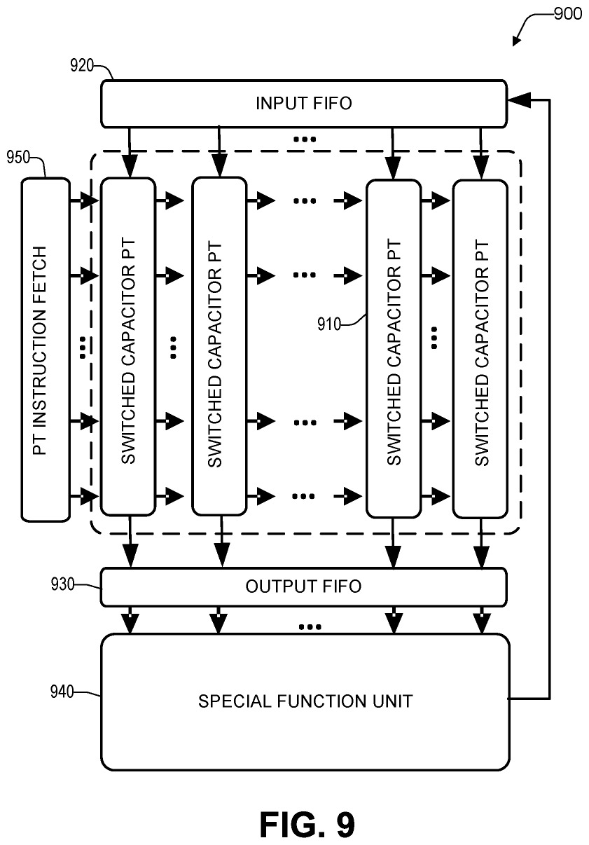

Reference is now made to FIG. 9, which illustrates certain elements of a computing system 900 that runs a neural network. The system 900 includes a plurality of processing tiles (PTs) 910 based on switched capacitors. In some embodiments, each switched capacitor PT 910 may include the MAC processor 800 of FIG. 8 or other mixed signal circuit herein. Thus, each switched capacitor PT 910 receives two vectors—an input vector X and a vector W of weights—from an input FIFO buffer 920, and performs splitting, vector multiplication, A/D conversion at less than full precision, and reconstruction of a digital output signal. The reconstructed digital output signal of each switched capacitor PT 910 is sent to an output FIFO buffer 930. A special function unit 940 includes a digital processor that performs computations corresponding to batch normalization, activation functions (e.g., sigmoid functions, rectified linear unit functions) and SoftMax functions. Outputs of one layer are sent to the input FIFO buffer 920 as an input vector for the next layer. A vector of weights for the next layer is also sent to the input FIFO buffer 920 and stored in local storage such as register files (not shown) in each switched capacitor PT 910, and another layer is processed.

A PT instruction fetch unit 950 fetches and issues instructions to the switched capacitor PTs 910 to control the operation of the switched capacitor PTs 910, the input of the vectors, and the output of the reconstructed digital outputs.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A system comprising:
a first circuit configured to:
split a first integer value into a first coarse value and a first fine value; and
split a second integer value into a second coarse value and a second fine value;
a second circuit configured to:
perform an analog multiply and accumulate (MAC) operation on the first and second coarse values to produce a first analog output signal;
perform an analog MAC operation on the first coarse value and the second fine value to produce a second analog output signal;
perform an analog MAC operation on the first fine value and the second coarse value to produce a third analog output signal; and
perform an analog MAC operation on the first and second fine values to produce a fourth analog output signal; and
a third circuit configured to perform analog-to-digital (A/D) conversion on and combine the analog output signals to produce a reconstructed digital output signal.

2. The system of claim 1, wherein the second circuit is further configured to perform most significant bit (MSB) skipping during the A/D conversion.

3. The system of claim 2, wherein the third circuit is configured to perform LSB truncation during the A/D conversion.

4. The system of claim 1, wherein the first circuit is configured to:
receive a first vector having M integer values and a second vector having M integer values, where integer M>1 and where the first vector includes the first integer value and additional integer values, and the second vector includes the second value and additional integer values;
split the first vector into a first coarse value vector and a first fine value vector; and
split the second vector into a second coarse value vector and a second fine value vector;
wherein the second circuit is configured to generate the first analog output signal as a dot product of the first and second coarse value vectors, the second analog output signal as a dot product of the first coarse and second fine value vectors, the third analog output signal as a dot product of the first fine and second coarse value vectors, and the fourth analog output signal as a dot produce of the first and second fine value vectors; and
wherein the third circuit is configured to perform the A/D conversion on and combine the analog output signals after M accumulations have been completed.

5. The system of claim 4, wherein after the M accumulations have been completed, the A/D conversion is performed at less than full precision, where full precision is defined as 2N+log 2(M), where N is bit width of the integer values.

6. The system of claim 5, wherein the second circuit comprises:
a first MAC engine configured to produce the first analog output signal;
a second MAC engine configured to produce the second analog output signal;
a third MAC engine configured to produce the third analog output signal; and
a fourth MAC engine configured to produce the fourth analog output signal; and
wherein the third circuit includes:
first, second, third and fourth A/D converters configured to perform A/D conversions on outputs of the first, second, third and fourth MAC engines, respectively, at less than full precision; and
a circuit configured to shift and sum digital signals outputted by the A/D converters to produce the reconstructed digital output signal.

7. The system of claim 6, wherein the second circuit includes a plurality of switched capacitor-based MAC engines configured to perform the MAC operations.

8. The system of claim 6, wherein MSB skipping in the first, second, third and fourth A/D converters causes between two and four of the most significant bits to be skipped.

9. The system of claim 6, wherein full-scale range of the A/D conversion is lower than dynamic range of the analog output signals to perform MSB skipping during the A/D conversion.

10. The system of claim 6, wherein:
the third circuit further includes first, second, third and fourth amplifiers configured to increase signal amplitude beyond full-scale input ranges of the first, second, third and fourth A/D converters, respectively.

11. The system of claim 6, wherein the A/D converters are configured to perform least significant bit (LSB) truncation.

12. The system of claim 4, wherein:
the integer values of first and second vectors are N bits wide;
the integer values of the coarse value vectors are K bits wide; and
the integer values of the fine value vectors are Y bits wide, where Y<N, K<N, and N, W and Y are integers.

13. The system of claim 12, wherein:
N=8, K=4 and Y=4;
each fine value has a rounded LSB; and
the digital output signal is reconstructed as
$${Y}_{R} = {2}^{8} Z 0 + {2}^{5} Z 1 + {2}^{5} Z 2 + {2}^{2} Z 3$$
where Y_{R} is the reconstructed digital output signal, and Z0, Z1, Z2 and Z3 are the A/D conversions of the first, second, third and fourth analog output signals, respectively.

14. The system of claim 12, wherein:
N=8, K=4 and Y=5; and
the digital output signal is reconstructed as
$${Y}_{R} = {2}^{8} Z 0 + {2}^{4} Z 1 + {2}^{4} Z 2 + Z 3$$
where Y_{R} is the reconstructed digital output signal, and Z0, Z1, Z2 and Z3 are the A/D conversions of the first, second, third and fourth analog output signals, respectively.

15. A computer-implemented method of multiplying first and second input vectors, each of the vectors having M integer values, the method comprising:
splitting values of the first input vector into first coarse value vectors and first fine value vectors;
splitting values of the second input vector into second coarse value vectors and second fine value vectors;
using a plurality of analog multiply and accumulate (MAC) units to generate a first analog signal representing a dot product of the first and second coarse value vectors, a second analog signal representing a dot product of the first coarse and second fine value vectors, a third analog signal representing a dot product of the first fine and second coarse value vectors, and a fourth analog signal representing a dot produce of the first and second fine value vectors; and
performing analog-to-digital (A/D) conversion on and combining the first, second, third and fourth analog signals to produce a digital output signal representing a dot product of the first and second input vectors.

16. The computer-implemented method of claim 15, further comprising performing most significant bit skipping during the A/D conversion.

17. A computing device for running a neural network, the device comprising:
a plurality of switched capacitor units configured to perform matrix multiplication on an input vector and a weight vector, each switched capacitor unit configured to:
split values of an input vector into first coarse value vectors and first fine value vectors;
split values of a weight vector into second coarse value vectors and second fine value vectors;
perform analog multiply and accumulate (MAC) operations to take a first dot product of the first and second coarse value vectors, a second dot product of the first coarse and second fine value vectors, a third dot product of the first fine and second coarse value vectors, and a fourth dot produce of the first and second fine value vectors; and
perform analog-to-digital (A/D) conversion on and combine the first, second, third and fourth dot products to produce a reconstructed digital signal; and
a digital processor programmed to apply activation functions to outputs of the switched capacitor units.

18. The computing device of claim 17, wherein each switched capacitor unit includes:
first, second, third and fourth switched capacitor-based MAC engines configured to produce the first, second, third and fourth dot products, respectively;
first, second, third and fourth A/D converters operative on analog signals representing the first, second, third and fourth dot products, respectively; and
a shift and sum circuit configured to combine outputs of the first, second, third and fourth A/D converters to produce the reconstructed digital signal.

19. The computing device of claim 18, wherein full-scale ranges of the A/D converters are lower than dynamic ranges of the analog signals representing the dot products to perform MSB skipping during the A/D conversion.

20. The computing device of claim 18, wherein each switched capacitor unit further includes first, second, third and fourth amplifiers configured to increase signal amplitude beyond full-scale input ranges of the first, second, third and fourth A/D converters, respectively.
